(19) United States
(12) Patent Application Publication
(10) Pub. No.: US 2021/0083132 A1
(43) Pub. Date: Mar. 18, 2021

(54) TRIPLE-JUNCTION ALL-PEROVSKITE PHOTOVOLTAIC DEVICE AND METHODS OF MAKING THE SAME

(71) Applicant: Jahahreeh Finley, Houston, TX (US)

(72) Inventor: Jahahreeh Finley, Houston, TX (US)

(21) Appl. No.: 16/568,510

(22) Filed: Sep. 12, 2019

(51) Int. Cl. H01L 31/0224; H01L 31/02; H01L 31/18; H01L 31/0216

(52) U.S. Cl. CPC H01L 31/022483; H01L 31/02167; H01L 31/18; H01L 31/02008

(57) ABSTRACT

The present invention provides a triple-junction photovoltaic device comprising three photoactive regions, each photoactive region comprising a perovskite material. A second sub-cell is comprised of a photoactive perovskite layer deposited directly onto a first sub-cell comprising a photoactive perovskite layer, creating a monolithically integrated device with two external electrical contacts (2T). A third sub-cell comprising a photoactive perovskite layer, engineered independently with two external electrical contacts, is stacked onto the second sub-cell of the monolithically integrated device, creating a novel triple-junction all-perovskite photovoltaic device with four external electrical contacts (4T). Also provided is a method of constructing a triple-junction all-perovskite photovoltaic device with four external electrical contacts and a method for perovskite material formation comprising inclusion of the organic stress-inducing compounds metformin and berberine to enhance perovskite crystal formation, stability, and perovskite solar cell efficiency.

### CROSS REFERENCE TO RELATED APPLICATIONS

Not Applicable

### FIELD OF THE INVENTION

The present invention relates to a triple-junction photovoltaic device comprising perovskite photoactive materials, methods for constructing such a device, and a method for perovskite material formation that enhances device efficiency and stability.

### BACKGROUND OF THE INVENTION

Sustainable sources of renewable energy are increasingly being sought as viable and cost-effective alternatives to the current dependence on fossil fuels. Lessening the deleterious environmental impact of electricity generation through fossil fuel use is imperative and solar energy harnessed via technologies including photovoltaic devices is widely considered as an attractive option to diversify energy sources. Widespread adoption of solar energy however has been hampered by concerns related to cost-effectiveness and reliability.

Photovoltaic (PV) devices utilizing organic-inorganic halide perovskites as light-absorbing layers has generated excitement due to their high optical absorption coefficients, long carrier diffusion lengths, and efficient charge collection. Perovskite materials are characterized by the formation of an ABX₃ crystal structure, where A is a large organic cation with a +1 charge (generally methylammonium (CH₃NH₃⁺) or formamidinium (NH₂CH═NH₂⁺), B is an inorganic cation with a +2 charge (typically lead (Pb²⁺) or tin (Sn²⁺)), and X is a halide anion with a −1 charge (e.g. iodide (I⁻) or bromide (Br⁻)) (Green M A, Ho-Baillie A, Snaith H J. The emergence of perovskite solar cells. Nat Photonics. 2014 Jun. 27(8): 506-514).

Perovskite materials can be manufactured into thin films for use in PV devices through the use of simple solution fabrication processes that utilize low-cost, readily available materials. Solar cells that contain perovskite thin films as absorber layers have also exhibited continually increasing power conversion efficiencies (PCI, the percentage of solar energy converted into electricity), as evidenced by an increase in lab-scale PCE from 3.8% in 2009 to greater than 23% in 2018, rivaling commercially available silicon-based solar cells as well as cadmium telluride (CdTe) and copper indium gallium selenide (CIGS) thin film solar cells (Rong Y, Hu Y, Mei A, et al. Challenges for commercializing perovskite solar cells. Science. 2018 Sep. 21; 361(6408). pii: eaat8235).

Planar perovskite solar cells (PSCs) are typically manufactured in a layered fashion, including a transparent conductive oxide (TCO)-coated glass substrate, a back-contact, and a thin film perovskite absorber layer “sandwiched” between an n-type semiconductor that functions as an electron transport layer (ETL) and a p-type semiconductor that acts as a hole-transport layer (HTL) (Rong Y, Hu Y, Mei A, et al. Challenges for commercializing perovskite solar cells. Science. 2018 Sep. 21; 361(6408). pii: eaat8235). Mechanistically, light absorption by the perovskite layer leads to the generation of electron-hole pairs, followed by charge separation in which photogenerated electrons may be injected into ETLs and holes (an empty electron state in a valence band) are injected into HTLs (Marchioro A, Teuscher J, Friedrich D, et al. Unravelling the mechanism of photoinduced charge transfer processes in lead iodide perovskite solar cells. Nat Photonics. 2014 Jan. 19(8): 250-255).

The efficiency of PSCs is also critically dependent on the selection of perovskite absorber layers that have appropriate bandgaps. The term bandgap refers to the energy difference (measured in electron volts (eV)) between the top of the valence band and the bottom of the conduction band and essentially represents the minimum energy requirement necessary to promote a valence electron to become a conduction electron. Conduction electrons may then move within perovskite polycrystalline films to act as charge carriers. PSCs that contain perovskite layers with appropriate bandgaps may also facilitate PSC efficiencies that surpass the Shockley-Queisser limit, a maximum theoretical amount of electrical energy extracted per photon of incoming sunlight (Kahmanna S, Loi M. Hot carrier solar cells and the potential of perovskites for breaking the Shockley-Queisser limit. J. Mater. Chem. C, 2019, 7, 2471-2486).

Compared to single-junction solar cells, development of cost-effective multi-junction PV devices may significantly improve solar panel efficiency for use in multiple applications, including solar panel arrays for spacecraft. Indeed, the Shockley-Queisser limit for single bandgap solar cells is approximately 33%, whereas multi-junction devices that use multiple bandgaps have record efficiencies of over 45%. Multi-junction PV devices are comprised of separate sub-cells that are arranged or “stacked” onto each other, leading to an increased efficiency in electricity generation through optimization of materials that absorb photons from various segments of the solar spectrum. Typically, the top sub-cell contains a photoactive region with the highest bandgap and absorbs high-energy photons. Lower-energy photons that are not absorbed by the top sub-cell are absorbed by photoactive regions in sub-cells placed below the top sub-cell, with lower sub-cells containing photoactive regions with bandgaps that successively decrease towards the bottom of the PV device (Hörantner M T, Leijtens T, Ziffer M E, et al. The Potential of Multijunction Perovskite Solar Cells. ACS Energy Lett. 2017, 2, 10, 2506-2513).

Two-terminal (2T) and four-terminal (4T) architectures are two primary designs for multi-junction (tandem) solar cells. In a 2T tandem cell, a second sub-cell is fabricated on top of a first sub-cell and the sub-cells are monolithically connected by a recombination layer or a tunnel junction, requiring only two external electrical contacts. However, in designing a 4T tandem cell, each sub-cell is fabricated on a separate substrate and operates independently. Two external electrical contacts are associated with each sub-cell and the sub-cells are subsequently physically stacked on top of each other, generating a tandem cell with four electrical contacts. Although 2T cells display a slight efficiency advantage over 4T cells due to a lower number of semi-transparent electrical contacts that are capable of photon absorption, potential solvent-induced damage of underlying layers during deposition renders 2T cell processing more difficult (Eperon G E, Hörantner M T, Snaith H J. Metal halide perovskite tandem and multiple-junction photovoltaics. Nature Reviews Chemistry volume 1, Article number: 0095 (2017)).

Although the long-term stability and degradation of PSCs have been well described and is considered the most challenging issue for PSC commercialization, several recent studies have surprisingly shown that exposure to external stressors may increase efficiency, stability, and photoluminescence of PSCs. Limited exposure to light, moisture, and oxygen has been shown to increase PSC photoluminescence and PCE. Intriguingly, such exposure leads to the production of reactive oxygen species (ROS, e.g. superoxide), which passivates or removes shallow surface trap states in perovskite polycrystalline films which may hinder carrier mobility (Brenes R, Guo D, Osherov A, et al. Metal Halide Perovskite Polycrystalline Films Exhibiting Properties of Single Crystals. Joule, Volume 1, Issue 1, 6 Sep. 2017, Pages 155-167). ROS are reactive chemical species containing oxygen that are also produced by living organisms including humans, generally as a byproduct of cellular metabolism. An accumulation of ROS that overwhelms an organism's ability to detoxify these reactive intermediates leads to oxidative stress, which is positively associated with numerous human diseases, including cancer, Alzheimer's disease, and diabetes (Pham-Huy L A, He H, Pham-Huy C. Free radicals, antioxidants in disease and health. Int J Biomed Sci. 2008 June; 4(2):89-96). However, just as beneficial levels of ROS increase the stability and efficiency of perovskite solar cells, beneficial levels of ROS have also been shown to be critical for human reproduction, learning and memory formation, and efficient immune system regulation, highlighting a novel link between stress-induced perovskite solar cell and human cell functionality (Finley J. Transposable elements, placental development, and oocyte activation: Cellular stress and AMPK links jumping genes with the creation of human life. Med Hypotheses. 2018 September; 118:44-54; Finley J. Facilitation of hippocampal long-term potentiation and reactivation of latent HIV-1 via AMPK activation: Common mechanism of action linking learning, memory, and the potential eradication of HIV-1. Med Hypotheses. 2018 July; 116:61-73).

### BRIEF SUMMARY OF THE INVENTION

An aspect of the present invention is a triple-junction all-perovskite photovoltaic device, comprising a first transparent conducting oxide substrate, a first electron-transport layer located on top of the first transparent conducting oxide substrate, a first perovskite halide film located on top of the first electron-transport layer, a first hole-transport layer located on top of the first perovskite halide film, a second electron-transport layer located on top of the first a hole-transport layer, a second perovskite halide film located on top of the second electron-transport layer, a second hole-transport layer located on top of the second perovskite halide film, a transparent conducting polymer layer located on top of the second hole-transport layer, a second transparent conducting oxide substrate located on top of the transparent conducting polymer layer, a third electron-transport layer located on top of the second transparent conducting oxide substrate, a third perovskite halide film located on top of the third electron-transport layer, a third hole-transport layer located on top of the third perovskite halide film, and metal layer located on top of the third hole-transport layer.

In an embodiment of the present invention, a recombination layer or a tunnel junction will not be included between the first hole-transport layer and the second electron transport layer in the triple-junction all-perovskite photovoltaic device. Although it is accepted by persons skilled in the art that a recombination layer or a tunnel junction is required to electrically connect the sub-cells of an all-perovskite monolithic multi-junction photovoltaic device, the inventor has found that the exclusion of a recombination layer or a tunnel junction represents a novel step that enhances the efficiency of triple-junction all-perovskite solar cells (McMeekin D P, Mahesh S, Noel N, et al. Solution-Processed All-Perovskite Multi-junction Solar Cells. Joule, Volume 3, Issue 2, 20 Feb. 2019, Pages 387-401).

Another aspect of the present invention is a method for manufacturing a triple junction all-perovskite photovoltaic device, the method comprising a first transparent conducting oxide substrate, a first electron-transport layer deposited on top of the first transparent conducting oxide substrate, a first perovskite halide film deposited on top of the first electron-transport layer, a first hole-transport layer deposited on top of the first perovskite halide film, a second electron-transport layer deposited on top of the first hole-transport layer, a second perovskite halide film deposited on top of the second electron-transport layer, a second hole-transport layer deposited on top of the second perovskite halide film, and a transparent conducting polymer layer deposited on top of the second hole-transport layer, fabricated as a monolithically integrated device with two external electrical contacts (2T).

In another embodiment of the present invention, a transparent conducting oxide substrate, an electron-transport layer deposited on top of the transparent conducting oxide substrate, a perovskite halide film deposited on top of the electron-transport layer, a hole-transport layer deposited on top of the perovskite halide film, and a metal layer deposited on top of the hole-transport layer are fabricated as an independent single-junction device with two external electrical contacts (2T).

In another embodiment of the present invention, the independently fabricated single-junction device with two external electrical contacts is physically stacked onto the second sub-cell of the monolithically integrated device, creating a novel triple-junction all-perovskite photovoltaic device with four external electrical contacts (4T). A triple-junction all-perovskite photovoltaic device with four external electrical contacts has not been developed previously or is not currently commercially available.

In another embodiment of the present invention, a triple-junction all-perovskite photovoltaic device with four external electrical contacts is encapsulated in a thin, plastic birefringent material.

Another aspect of the present invention is a method of forming a perovskite halide thin film, the method including the application of a solution to a substrate, the solution comprising an organic methylammonium (CH₃NH₃⁺) cation or an organic formamidinium (NH₂CH═NH₂⁺) cation, or both methylammonium (CH₃NH₃⁺) and formamidinium (NH₂CH═NH₂⁺) cations.

In another embodiment of the present invention, the solution for forming a perovskite halide thin film comprises an inorganic lead (Pb²⁺) cation or both inorganic lead (Pb²⁺) and inorganic tin (Sn²⁺) cations.

In another embodiment of the present invention, the solution for forming a perovskite halide thin film comprises the anion iodide (I⁻).

In another embodiment of the present invention, perovskite materials formed from crystallization of the solution are characterized by an ABX₃ crystal structure, where A comprises methylammonium (CH₃NH₃⁺) or formamidinium (NH₂CH═NH₂⁺), or both methylammonium (CH₃NH₃⁺) and formamidinium (NH₂CH═NH₂⁺), B comprises lead (Pb²⁺) or both lead (Pb²⁺) and tin (Sn²⁺), and X comprises the anion iodide (I⁻).

In another embodiment of the present invention, the solution for forming a perovskite halide thin film comprises an organic compound from the biguanide class.

In another embodiment of the present invention, the solution for forming a perovskite halide thin film comprises an isoquinoline alkaloid compound.

In another embodiment of the present invention, the solution for forming a perovskite halide thin film comprises the additive 1,8-diiodooctane (DIO).

### BRIEF DESCRIPTION OF THE DRAWINGS

FIG. 1a illustrates schematically a perovskite-based single junction photovoltaic device, according to embodiments of the present invention.

FIG. 1b illustrates schematically a monolithically fabricated all-perovskite multi-junction photovoltaic device, according to embodiments of the present invention.

FIG. 2 illustrates schematically a triple-junction all-perovskite photovoltaic device, according to embodiments of the present invention.

FIG. 3 illustrates a schematic of a method of forming a perovskite halide thin film, according to embodiments of the present invention.

### DETAILED DESCRIPTION OF THE INVENTION

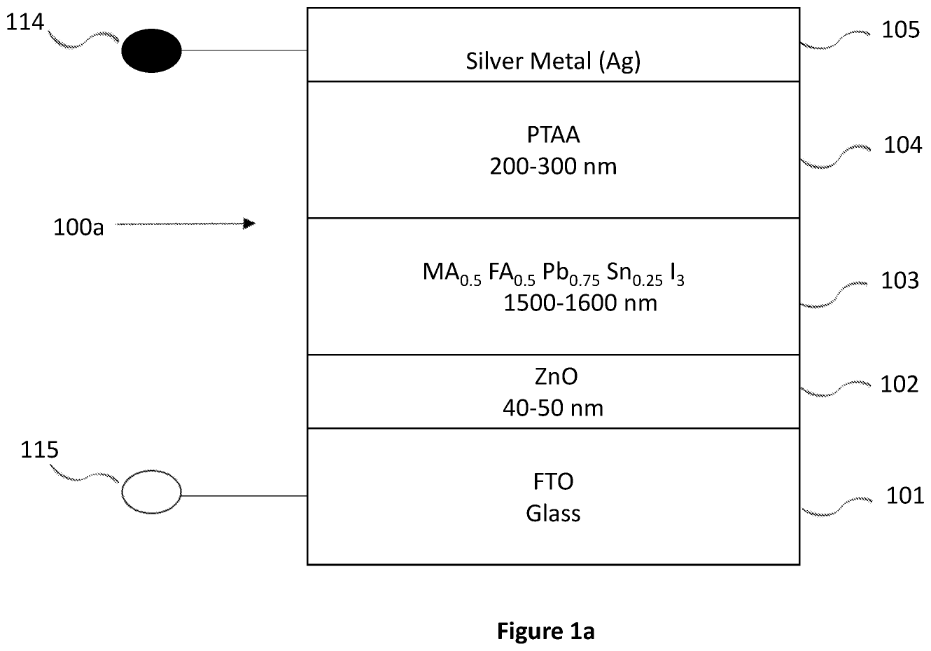

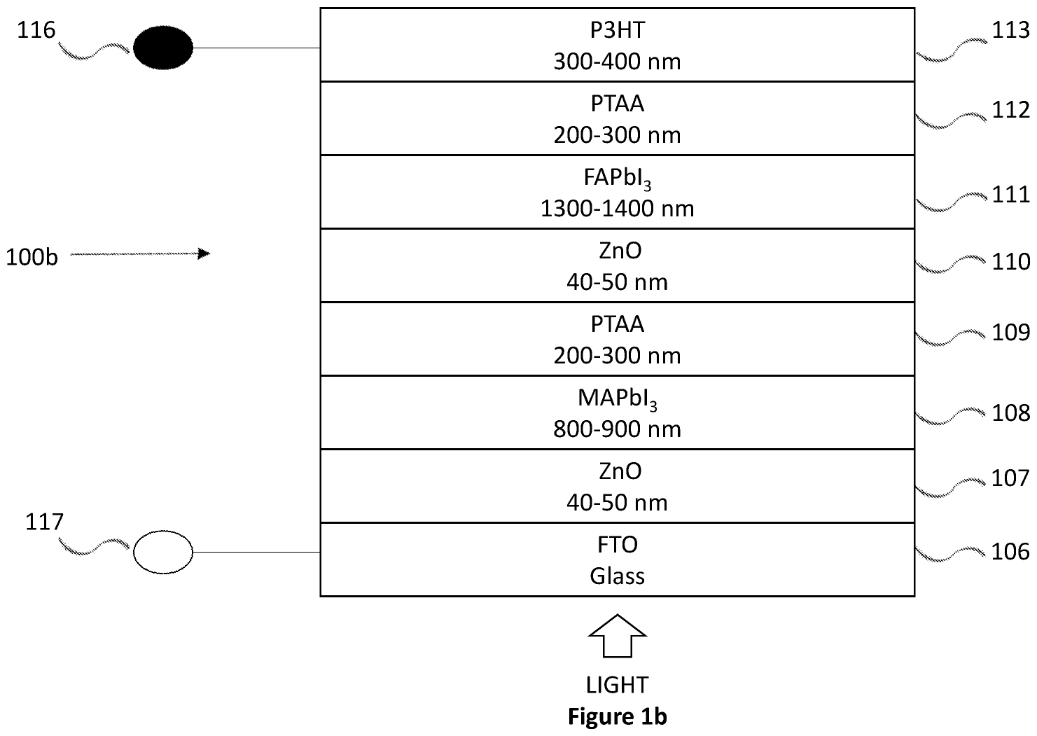

FIG. 1a illustrates schematically a perovskite-based single junction photovoltaic device 100a, according to embodiments the present invention. In FIG. 1a, 100a comprises a transparent conducting oxide (TCO) substrate 101, an electron transport layer (ETL) 102, a photoactive region 103, a hole transport layer (HTL) 104, a metal electrode 105, and two external electrical contacts 114 and 115.

In FIG. 1a, the device 100a comprises a TCO substrate 101, wherein the TCO substrate 101 consists of fluorine-doped tin oxide (FTO)-coated glass. An external electrical contact 115 is attached to the TCO substrate 101. An ETL 102 is located on top of the FTO-coated glass layer 101, wherein the ETL 102 consists of zinc oxide (ZnO). The ETL 102 consisting of ZnO has a width (x) of greater than or equal to 40 nanometers (nm) but less than or equal to 50 nm (40 nm≤x≤50 nm). A photoactive region 103 is located on top of the ETL 102, wherein the photoactive region 103 consists of a perovskite material of the formula A_{1-y}A′_{y}B_{1-z}B′_{z}X₃, wherein A is a methylammonium cation (CH₃NH₃⁺), A′ is a formamidinium cation (NH₂CH═NH₂⁺), B is a lead cation (Pb²⁺), B′ is a tin cation (Sn²⁺), and X is iodide (I⁻), with the value of y equal to 0.5 and the value of z equal to 0.25 (MA_{0.5}FA_{0.5} Pb_{0.75} Sn_{0.25} I₃). The photoactive region 103 has a width (x) of greater than or equal to 1,500 nm but less than or equal to 1,600 nm (1,500 nm≤x≤1,600 nm). An HTL 104 is located on top of the photoactive region 103, wherein the HTL 104 consists of the polymer poly(triarylamine) (PTAA). The HTL 104 consisting of PTAA has a width (x) of greater than or equal to 200 nm but less than or equal to 300 nm (200 nm≤x≤300 nm). A metal electrode 105 is located on top of the HTL 104, wherein the metal electrode 105 consists of silver (Ag). An external electrical contact 114 is attached to the metal electrode 105.

FIG. 1b illustrates a monolithically fabricated all-perovskite multi-junction photovoltaic device 100b, according to the present invention. In FIG. 1b, 100b comprises a transparent conducting oxide (TCO) substrate 106, a first ETL 107, a first photoactive region 108, a first HTL 109, a second ETL 110, a second photoactive region 111, a second HTL 112, a transparent conducting polymer layer 113, and two external electrical contacts 116 and 117.

In FIG. 1b, the device 100b comprises a TCO substrate 106, wherein the TCO substrate 106 consists of fluorine-doped tin oxide (FTO)-coated glass. The TCO substrate 106 will function as a front electrode located on the surface of the device that is exposed to sunlight. An external electrical contact 117 is attached to the TCO substrate 106. A first ETL 107 is located on top of the FTO-coated glass layer 106, wherein the first ETL 107 consists of zinc oxide (ZnO). The first ETL 107 consisting of ZnO has a width (x) of greater than or equal to 40 nm but less than or equal to 50 nm (40 nm≤x≤50 nm). A first photoactive region 108 is located on top of the first ETL 107, wherein the first photoactive region 108 consists of a perovskite material of the formula ABX₃, wherein A is a methylammonium cation (CH₃NH₃⁺), B is a lead cation (Pb²⁺), and X is iodide (I⁻) (MAPbI₃). The first photoactive region 108 has a width (x) of greater than or equal to 800 nm but less than or equal to 900 nm (800 nm≤x≤900 nm). A first HTL 109 is located on top of the first photoactive region 108, wherein the first HTL 109 consists of the polymer poly(triarylamine) (PTAA). The first HTL 109 consisting of PTAA has a width (x) of greater than or equal to 200 nm but less than or equal to 300 nm (200 nm≤x≤300 nm). A second ETL 110 is located on top of the first HTL 109, wherein the second ETL 110 consists of zinc oxide (ZnO). The second ETL 110 consisting of ZnO has a width (x) of greater than or equal to 40 nm but less than or equal to 50 nm (40 nm≤x≤50 nm). A second photoactive region 111 is located on top of the second ETL 110, wherein the second photoactive region 111 consists of a perovskite material of the formula ABX₃, wherein A is a formamidinium cation (NH₂CH═NH₂⁺), B is a lead cation (Pb²⁺), and X is iodide (I⁻) (FAPbI₃). The second photoactive region 111 has a width (x) of greater than or equal to 1,300 nm but less than or equal to 1,400 nm (1,300 nm≤x≤1,400 nm). A second HTL 112 is located on top of the second photoactive region 111, wherein the second HTL 112 consists of the polymer poly(triarylamine) (PTAA). The second HTL 112 consisting of PTAA has a width (x) of greater than or equal to 200 nm but less than or equal to 300 nm (200 nm≤x≤300 nm). A transparent conducting polymer layer 113 is located on top of the second HTL 112, wherein the transparent conducting polymer layer 113 consists of the polymer poly(3-hexylthiophene) (P3HT). The transparent conducting polymer layer 113 consisting of P3HT has a width (x) of greater than or equal to 300 nm but less than or equal to 400 nm (300 nm≤x≤400 nm). An external electrical contact 116 is attached to the transparent conducting polymer layer 113.

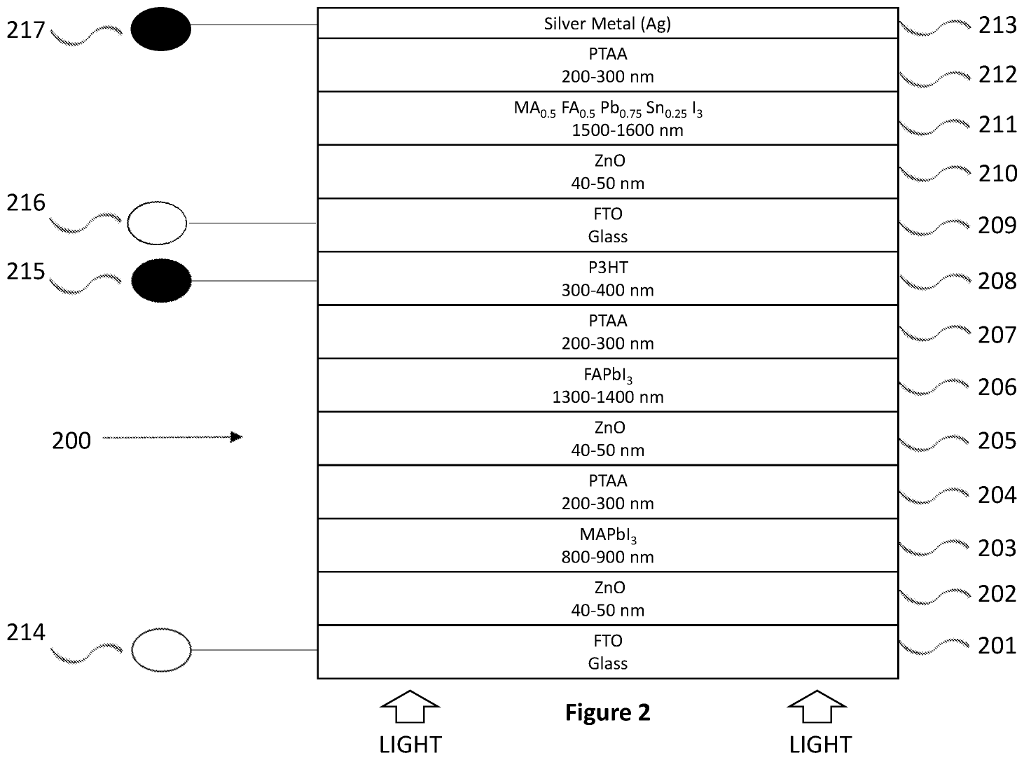

FIG. 2 illustrates schematically a triple-junction all-perovskite photovoltaic device with four external electrical contacts, according to embodiments of the present invention. In FIG. 2, the device 200 is manufactured by placing the perovskite-based single junction photovoltaic device 100a on top of the monolithically fabricated all-perovskite multi-junction photovoltaic device 100b, wherein the wherein the TCO substrate 101 of device 100a makes contact with the transparent conducting polymer layer 113 of device 100b.

In FIG. 2 the device 200 comprises a first TCO substrate 201, wherein the TCO substrate 201 consists of fluorine-doped tin oxide (FTO)-coated glass. The TCO substrate 201 will function as a front electrode located on the surface of the device that is exposed to sunlight. An external electrical contact 214 is attached to the TCO substrate 201. A first ETL 202 is located on top of the first FTO-coated glass layer 201, wherein the first ETL 202 consists of zinc oxide (ZnO). The first ETL 202 consisting of ZnO has a width (x) of greater than or equal to 40 nm but less than or equal to 50 nm (40 nm≤x≤50 nm). A first photoactive region 203 is located on top of the first ETL 202, wherein the first photoactive region 203 consists of a perovskite material of the formula ABX₃, wherein A is a methylammonium cation (CH₃NH₃⁺), B is a lead cation (Pb²⁺), and X is iodide (I⁻) (MAPbI₃). The first photoactive region 203 has a width (x) of greater than or equal to 800 nm but less than or equal to 900 nm (800 nm≤x≤900 nm). A first HTL 204 is located on top of the first photoactive region 203, wherein the first HTL 204 consists of the polymer poly(triarylamine) (PTAA). The first HTL 204 consisting of PTAA has a width (x) of greater than or equal to 200 nm but less than or equal to 300 nm (200 nm≤x≤300 nm). A second ETL 205 is located on top of the first HTL 204, wherein the second ETL 205 consists of zinc oxide (ZnO). The second ETL 205 consisting of ZnO has a width (x) of greater than or equal to 40 nm but less than or equal to 50 nm (40 nm≤x≤50 nm). A second photoactive region 206 is located on top of the second ETL 205, wherein the second photoactive region 206 consists of a perovskite material of the formula ABX₃, wherein A is a formamidinium cation (NH₂CH═NH₂⁺), B is a lead cation (Pb²⁺), and X is iodide (I⁻) (FAPbI₃). The second photoactive region 206 has a width (x) of greater than or equal to 1,300 nm but less than or equal to 1,400 nm (1,300 nm≤x≤1,400 nm). A second HTL 207 is located on top of the second photoactive region 206, wherein the second HTL 207 consists of the polymer poly(triarylamine) (PTAA). The second HTL 207 consisting of PTAA has a width (x) of greater than or equal to 200 nm but less than or equal to 300 nm (200 nm≤x≤300 nm). A transparent conducting polymer layer 208 is located on top of the second HTL 207, wherein the transparent conducting polymer layer 208 consists of the polymer poly(3-hexylthiophene) (P3HT). The transparent conducting polymer layer 208 consisting of P3HT has a width (x) of greater than or equal to 300 nm but less than or equal to 400 nm (300 nm≤x≤400 nm). An external electrical contact 215 is attached to the transparent conducting polymer layer 208.

A second TCO substrate 209 is located on top of the transparent conducting polymer layer 208, wherein the TCO substrate 209 consists of fluorine-doped tin oxide (FTO)-coated glass. An external electrical contact 216 is attached to the TCO substrate 209. A third ETL 210 is located on top of the FTO-coated glass layer 209, wherein the third ETL 210 consists of zinc oxide (ZnO). The third ETL 210 consisting of ZnO has a width (x) of greater than or equal to 40 nm but less than or equal to 50 nm (40 nm≤x≤50 nm). A third photoactive region 211 is located on top of the third ETL 210, wherein the third photoactive region 211 consists of a perovskite material of the formula A_{1-y}A′_{y}B_{1-z}B′_{z}X₃, wherein A is a methylammonium cation (CH₃NH₃⁺), A′ is a formamidinium cation (NH₂CH═NH₂⁺), B is a lead cation (Pb²⁺), B′ is a tin cation (Sn²⁺), and X is iodide (I⁻), with the value of y equal to 0.5 and the value of z equal to 0.25 (MA_{0.5} FA_{0.5} Pb_{0.75} Sn_{0.25} I₃). The third photoactive region 211 has a width (x) of greater than or equal to 1,500 nm but less than or equal to 1,600 nm (1,500 nm≤x≤1,600 nm). A third HTL 212 is located on top of the third photoactive region 211, wherein the third HTL 212 consists of the polymer poly(triarylamine) (PTAA). The third HTL 212 consisting of PTAA has a width (x) of greater than or equal to 200 nm but less than or equal to 300 nm (200 nm≤x≤300 nm). A metal electrode 213 is located on top of the third HTL 212, wherein the metal electrode 213 consists of silver (Ag). An external electrical contact 217 is attached to the metal electrode 213.

The triple-junction all-perovskite photovoltaic device with four external electrical contacts 200 is also encapsulated in a thin, plastic birefringent coating comprising the polymer polyimide. Although PV devices used in solar panels are most often encapsulated in glass to provide protection from environmental factors, polyimide films have been shown to be 100 times thinner and 200 times lighter than glass used for PV devices (“New superstrate material enables flexible, lightweight and efficient thin film solar modules,” https://www.sciencedaily.com/releases/2011/06/110609084806.htm, last accessed, Aug. 18, 2019). Polyimide films are lightweight and flexible, exhibit high resistance to heat and chemicals, and are used in thermal blankets on spacecraft for protection from extreme heat and cold in deep space (“Extreme Versatility and Thermal Performance Provides Unlimited Potential,” https://www.dupont.com/electronic-materials/polyimide-films.html, last accessed, Aug. 18, 2019). Polyimide thin films also exhibit birefringence (i.e. the refraction of light when passing from one medium to another), potentially enhancing absorption of high-energy photons in PV solar cell devices, leading to an increase in power conversion efficiencies (PCE) (Lee C, Seo J, Shul Y, Han H. Optical Properties of Polyimide Thin Films. Effect of Chemical Structure and Morphology. Polymer Journal 35, 578-585 (2003)).

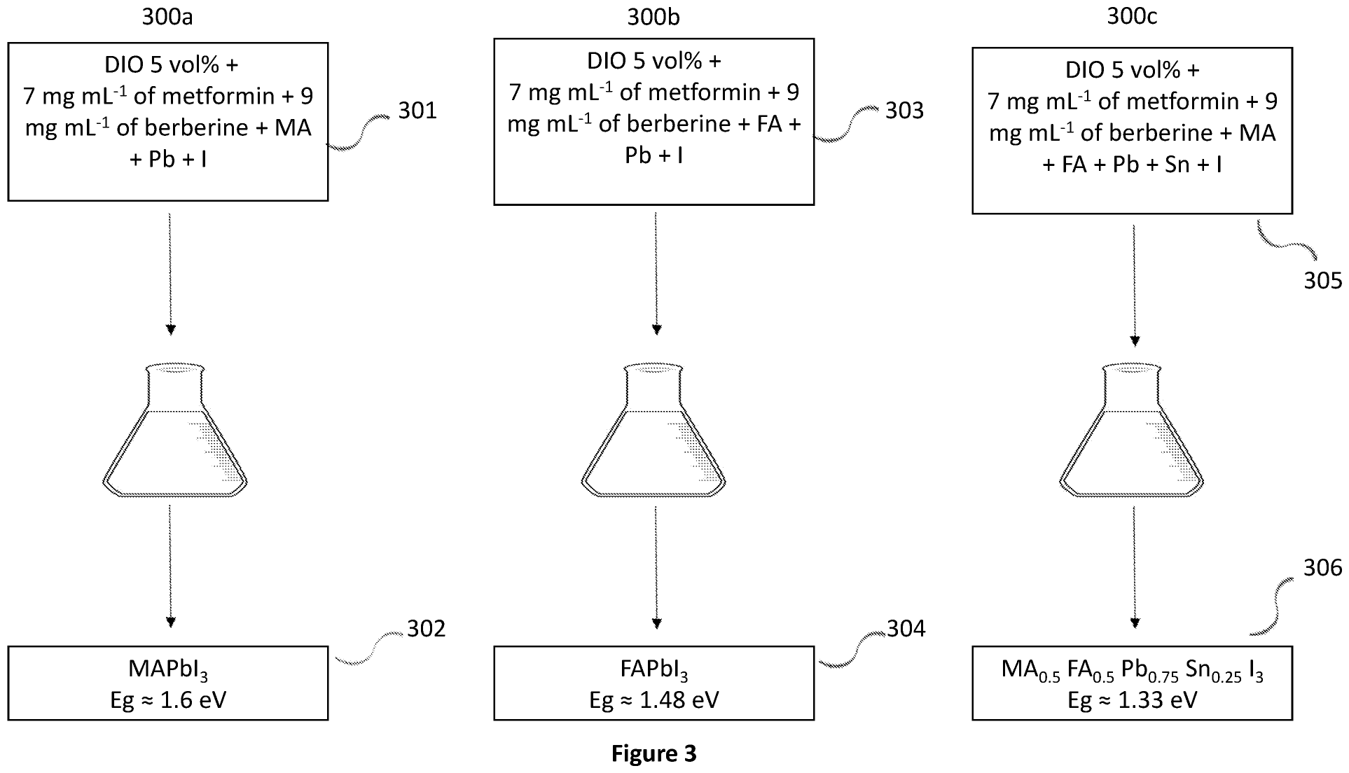

FIG. 3 illustrates a schematic of a method of forming a perovskite halide thin film, according to embodiments of the present invention. In FIG. 3, 300a, 300b, and 300c, each comprises a method of forming a perovskite halide thin film, wherein each method comprises a perovskite precursor solution. The perovskite precursor solutions comprising methods 300a, 300b, and 300c, each consist of specific quantities of the biguanide metformin, the isoquinoline alkaloid berberine, and the additive 1,8-diiodooctane (DIO). As noted above, beneficial levels of reactive oxygen species (ROS) increase the stability and efficiency of perovskite solar cells and are also critical for human reproduction, learning and memory formation, and efficient immune system regulation. The biguanide metformin beneficially increases ROS levels in human cells and metformin is also efficacious for the treatment of type 2 diabetes mellitus in human patients (Mogavero A, Maiorana M V, Zanutto S, et al. Metformin transiently inhibits colorectal cancer cell proliferation as a result of either AMPK activation or increased ROS production. Sci Rep. 2017 Nov. 22; 7(1):15992; Sanchez-Rangel E, Inzucchi S E. Metformin: clinical use in type 2 diabetes. Diabetologia. 2017 September; 60(9):1586-1593). The alkaloid berberine also beneficially increases the levels of ROS in human cells and has also shown efficacious results in human clinical trials for the treatment of type 2 diabetes mellitus (Xie J, Xu Y, Huang X, et al. Berberine-induced apoptosis in human breast cancer cells is mediated by reactive oxygen species generation and mitochondrial-related apoptotic pathway. Tumour Biol. 2015 February; 36(2):1279-88; Yin J, Xing H, Ye J. Efficacy of berberine in patients with type 2 diabetes mellitus. Metabolism. 2008 May; 57(5):712-7).

Additionally, metformin has been shown to facilitate the adsorption of lead (Pb²⁺) ions from an aqueous solution, indicating that metformin may enhance and stabilize perovskite crystal formation (Shahabuddin S, Tashakori C, Kamboh M A, et al. Kinetic and equilibrium adsorption of lead from water using magnetic metformin-substituted SBA-15. Environ. Sci.: Water Res. Technol., 2018, 4, 549-558). Berberine has also been shown to be a blue light-absorbing photosensitizer, thus increasing the probability of “hot carrier” formation in perovskite solar cells, allowing such cells to obtain PCEs that surpass the Shockley-Queisser limit (Siewert B, Vrabl P, Hammerle F, Binggerb I, Stuppner H. A convenient workflow to spot photosensitizers revealed photo-activity in basidiomycetes. RSC Adv., 2019, 9, 4545-4552; Guzelturk B, Belisle R A, Smith M D, et al. Terahertz Emission from Hybrid Perovskites Driven by Ultrafast Charge Separation and Strong Electron-Phonon Coupling. Adv Mater. 2018 March; 30(11)). All-perovskite PV devices that utilize both metformin and berberine to enhance and stabilize perovskite crystal formation for the development and deposition of perovskite halide thin films have not been developed previously or are not currently commercially available.

In FIG. 3, 300a comprises a method of forming a perovskite halide thin film 302. The method of forming a perovskite halide thin film 302 comprises the formation of a perovskite precursor solution 301, wherein the perovskite precursor solution 301 comprises DIO 5 vol %, 7 mg mL⁻¹ of metformin, 9 mg mL⁻¹ of berberine, and the ions methylammonium (CH₃NH₃⁺), lead (Pb²⁺), and iodide (I⁻). After perovskite crystallization and deposition, the perovskite halide thin film 302 formed has the formula ABX₃, wherein A is a methylammonium cation (CH₃NH₃⁺), B is a lead cation (Pb²⁺), and X is iodide (I⁻) (MAPbI₃). The perovskite halide thin film 302 has a bandgap (E_{g}) approximately equal to 1.6 electron volts (eV). 300b comprises a method of forming a perovskite halide thin film 304. The method of forming a perovskite halide thin film 304 comprises the formation of a perovskite precursor solution 303, wherein the perovskite precursor solution 303 comprises DIO 5 vol %, 7 mg mL⁻¹ of metformin, 9 mg mL⁻¹ of berberine, and the ions formamidinium (NH₂CH═NH₂⁺), lead (Pb²⁺), and iodide (I⁻). After perovskite crystallization and deposition, the perovskite halide thin film 304 formed has the formula ABX₃, wherein A is a formamidinium cation (NH₂CH═NH₂⁺), B is a lead cation (Pb²⁺), and X is iodide (I⁻) (FAPbI₃). The perovskite halide thin film 304 has a bandgap (E_{g}) approximately equal to 1.48 electron volts (eV). 300c comprises a method of forming a perovskite halide thin film 306. The method of forming a perovskite halide thin film 306 comprises the formation of a perovskite precursor solution 305, wherein the perovskite precursor solution 305 comprises DIO 5 vol %, 7 mg mL⁻¹ of metformin, 9 mg mL⁻¹ of berberine, and the ions methylammonium (CH₃NH₃⁺), formamidinium (NH₂CH═NH₂⁺), lead (Pb²⁺), tin (Sn²⁺), and iodide (I⁻). After perovskite crystallization and deposition, the perovskite halide thin film 306 formed has the formula A_{1-y}A′_{y}B_{1-z}B′_{z}X₃, wherein A is a methylammonium cation (CH₃NH₃⁺), A′ is a formamidinium cation (NH₂CH═NH₂⁺), B is a lead cation (Pb²⁺), B′ is a tin cation (Sn²⁺), and X is iodide (I⁻), with the value of y equal to 0.5 and the value of z equal to 0.25 (MA_{0.5} FA_{0.5} Pb_{0.75} Sn_{0.2} I₃). The perovskite halide thin film 306 has a bandgap (E_{g}) approximately equal to 1.33 electron volts (eV).

Although the present invention has been described in reference to specific embodiments, the written description and the embodiments described therein are illustrative and do not limit the present invention. Those skilled in the art may recognize modifications or variations to the present invention without departing from the underlying scope and spirit of the present invention and all such modifications or variations are intended to be included in the appended claims.

What is claimed is:

1. A triple-junction all-perovskite photovoltaic device comprising:
a first transparent conducting oxide (TCO) substrate;
a first electron-transport layer (ETL) located on top of the first TCO substrate;
a first perovskite halide film located on top of the first ETL;
a first hole-transport layer (HTL) located on top of the first perovskite halide film;
a second ETL located on top of the first HTL;
a second perovskite halide film located on top of the second ETL;
a second HTL located on top of the second perovskite halide film;
a transparent conducting polymer layer located on top of the second HTL;
a second TCO substrate located on top of the transparent conducting polymer;
a third ETL located on top of the second TCO substrate;
a third perovskite halide film located on top of the third ETL;
a third HTL located on top of the third perovskite halide film; and
a metal layer located on top of the third HTL.

2. The device of claim 1,
wherein the first TCO substrate consists of fluorine-doped tin oxide (FTO)-coated glass,
wherein the first TCO substrate has an external electrical contact attached, and
wherein the first TCO substrate is located on the surface of the device that is exposed to sunlight.

3. The device of claim 1,
wherein the first ETL consists of zinc oxide (ZnO), and
wherein the first ETL has a width greater than or equal to 40 nanometers but less than or equal to 50 nanometers.

4. The device of claim 1,
wherein the first photoactive region consists of a perovskite material of the formula ABX₃ wherein A is a methylammonium cation (CH3NH3+), B is a lead cation (Pb2+), and X is iodide (I−),
wherein the first photoactive region has a bandgap approximately equal to 1.6 electron volts, and
wherein the first photoactive region has a width greater than or equal to 800 nanometers but less than or equal to 900 nanometers.

5. The device of claim 1,
wherein the first HTL consists of the polymer poly(triarylamine) (PTAA), and
wherein the first HTL has a width greater than or equal to 200 nanometers but less than or equal to 300 nanometers.

6. The device of claim 1,
wherein the second ETL consists of zinc oxide (ZnO), and
wherein the second ETL has a width greater than or equal to 40 nanometers but less than or equal to 50 nanometers.

7. The device of claim 1,
wherein the second photoactive region consists of a perovskite material of the formula ABX₃ wherein A is a formamidinium cation (NH₂CH═NH₂⁺), B is a lead cation (Pb²⁺), and X is iodide (I⁻),
wherein the second photoactive region has a bandgap approximately equal to 1.48 electron volts, and
wherein the second photoactive region has a width greater than or equal to 1,300 nanometers but less than or equal to 1,400 nanometers.

8. The device of claim 1,
wherein the second HTL consists of the polymer poly(triarylamine) (PTAA), and
wherein the second HTL has a width greater than or equal to 200 nanometers but less than or equal to 300 nanometers.

9. The device of claim 1,
wherein the transparent conducting polymer layer has an external electrical contact attached,
wherein the transparent conducting polymer layer consists of the polymer poly(3-hexylthiophene) (P3HT), and
wherein the transparent conducting polymer layer has a width greater than or equal to 300 nanometers but less than or equal to 400 nanometers.

10. The device of claim 1,
wherein the second TCO substrate consists of fluorine-doped tin oxide (FTO)-coated glass, and
wherein the second TCO substrate has an external electrical contact attached.

11. The device of claim 1,
wherein the third ETL consists of zinc (ZnO), and
wherein the third ETL has a width greater than or equal to 40 nanometers but less than or equal to 50 nanometers.

12. The device of claim 1,
wherein the third photoactive region consists of a perovskite material of the formula A_{1-y}A′_{y}B_{1-z}B′_{z}X₃ wherein A is a methylammonium cation (CH₃NH₃⁺), A′ is a formamidinium cation (NH₂CH═NH₂⁺), B is a lead cation (Pb²⁺), B′ is a tin cation (Sn²⁺), and X is iodide (I⁻) and the value of y is equal to 0.5 and the value of z is equal to 0.25,
wherein the third photoactive region has a bandgap approximately equal to 1.33 electron volts, and
wherein the third photoactive region has a width greater than or equal to 1,500 nanometers but less than or equal to 1,600 nanometers.

13. The device of claim 1,
wherein the third HTL consists of the polymer poly(triarylamine) (PTAA), and
wherein the third HTL has a width greater than or equal to 200 nanometers but less than or equal to 300 nanometers.

14. The device of claim 1,
wherein the metal layer consists of silver (Ag), and
wherein the metal layer has an external electrical contact attached to it.

15. The device of claim 1 wherein the triple-junction all-perovskite photovoltaic device is encapsulated in a thin, plastic material comprising polyimide.

16. A method for manufacturing a triple junction all-perovskite photovoltaic device with four external electrical contacts, the method comprising:
placing a perovskite-based single junction photovoltaic device with two external electrical contacts on top of a monolithically fabricated all-perovskite multi-junction photovoltaic device with two external electrical contacts, and
wherein the transparent conducting oxide substrate of the perovskite-based single junction photovoltaic device is deposited on top of and makes contact with the transparent conducting polymer layer of the monolithically fabricated all-perovskite multi-junction photovoltaic device.

17. The method of claim 16,
wherein the perovskite-based single junction photovoltaic device with two external electrical contacts comprises:
a transparent conducting oxide substrate with an external electrical contact attached;
an electron-transport layer deposited on top of the transparent conducting oxide substrate;
a perovskite halide film deposited on top of the electron-transport layer;
a hole-transport layer deposited on top of the perovskite halide film; and
a metal layer with an external electrical contact attached deposited on top of the hole-transport layer.

18. The method of claim 16,
wherein the monolithically fabricated all-perovskite multi-junction photovoltaic device with two external electrical contacts comprises:
a first transparent conducting oxide substrate with an external electrical contact attached;
a first electron-transport layer deposited on top of the first transparent conducting oxide substrate;
a first perovskite halide film deposited on top of the first electron-transport layer;
a first hole-transport layer deposited on top of the first perovskite halide film;
a second electron-transport layer deposited on top of the first hole-transport layer;
a second perovskite halide film deposited on top of the second electron-transport layer;
a second hole-transport layer deposited on top of the second perovskite halide film; and
a transparent conducting polymer layer with an external electrical contact attached deposited on top of the second hole-transport layer.

19. A method of forming a perovskite halide thin film, the method comprising:
forming and depositing a perovskite precursor solution onto a substrate,
wherein the perovskite precursor solution comprises:
(i) 1,8-diiodooctane (DIO) 5 vol %;
(ii) 7 mg mL⁻¹ of metformin;
(iii) 9 mg mL⁻¹ of berberine;
(iv) Methylammonium (CH₃NH₃⁺);
(v) Lead (Pb²⁺); and
(vi) Iodide (I⁻).

20. The method of claim 19,
wherein the perovskite precursor solution comprises:
(i) 1,8-diiodooctane (DIO) 5 vol %;
(ii) 7 mg mL⁻¹ of metformin;
(iii) 9 mg mL⁻¹ of berberine;
(iv) Formamidinium (NH₂CH═NH₂⁺);
(v) Lead (Pb²⁺); and
(vi) Iodide (I⁻).

21. The method of claim 19,
wherein the perovskite precursor solution comprises:
(i) 1,8-diiodooctane (DIO) 5 vol %;
(ii) 7 mg mL⁻¹ of metformin;
(iii) 9 mg mL⁻¹ of berberine;
(iv) Methylammonium (CH₃NH₃⁺);
(v) Formamidinium (NH₂CH═NH₂⁺);
(vi) Lead (Pb²⁺);
(vii) Tin (Sn²⁺); and
(viii) Iodide (I⁻).
